(19) United States
(12) Patent Application Publication
(10) Pub. No.: US 2012/0032339 A1
(43) Pub. Date: Feb. 9, 2012

(54) INTEGRATED CIRCUIT STRUCTURE WITH THROUGH VIA FOR HEAT EVACUATING

(75) Inventor: Shing Hwa Renn, Taipei City (TW)

(73) Assignee: NANYA TECHNOLOGY CORPORATION, KUEISHAN (TW)

(21) Appl. No.: 12/850,194

(22) Filed: Aug. 4, 2010

(51) Int. Cl. H01L 23/538; H01L 23/34

(52) U.S. Cl. 257/774; 257/E23.174; 257/E23.08

(57) ABSTRACT

An integrated circuit structure includes a semiconductor substrate, an active device disposed on a first region of the semiconductor substrate, a layer stack disposed on a second region of the semiconductor substrate, a through via penetrating through the layer stack and the semiconductor substrate, and a third dielectric layer disposed between the through via and the semiconductor substrate. In one embodiment of the present invention, the layer stack includes a first dielectric layer disposed on the semiconductor substrate and a heat-conducting member disposed on the first dielectric layer.

### TECHNICAL FIELD

The present invention relates to an integrated circuit structure. More particularly, the present invention relates to an integrated circuit structure with a through via for heat evacuating.

### BACKGROUND

Packaging technology for integrated circuit structures has been to continuously developed to meet the demand toward miniaturization and mounting reliability. Recently, as the miniaturization and high functionality of electric and electronic products are required, various techniques have been disclosed in the art.

By using a stack of at least two chips, in the case of a memory device for example, it is possible to produce a product having a memory capacity which is two times as large as that obtainable through semiconductor integration processes. Also, a stack package provides advantages not only through an increase in memory capacity but also in view of a mounting density and mounting area utilization efficiency. Due to this fact, research and development of stack package technology has accelerated.

As an example of a stack package, a through-silicon via (TSV) has been disclosed in the art. The stack package using a TSV has a structure in which the TSV is disposed in a chip so that chips are physically and electrically connected with each other through the TSV. A vertical hole is defined through a predetermined portion of each chip at a wafer level. A dielectric layer is disposed on the sidewall of the vertical hole. With a metal layer disposed on the dielectric layer, an electrolytic substance, i.e. a metal, is filled into the vertical hole through an electroplating process to form a TSV. Next, the TSV is exposed through back-grinding of the backside of a wafer.

After the wafer is sawed and separated into individual chips, at least two chips can be vertically stacked, one atop the other, on one of the substrates using one or more of the TSV. Thereupon, the upper surface of the substrate including the stacked chips is molded, and solder balls are mounted on the lower surface of the substrate, by which the manufacture of a stack package is completed.

As is known, semiconductor chips generate heat while operating. Different thermal expansion coefficients between silicon and metal or to metallic substance can causes stresses in a semiconductor chip as its temperature rises and falls during operation, which is a phenomenon that can significantly deteriorate the integrity and the reliability of silicon/metal junctions in a chip during the operation of the semiconductor chip. Displacements of respective materials vary when operation temperature is changed, and if the stress caused by the difference in thermal expansion coefficient cannot be relieved, a fracture of the package may result.

Furthermore, the heat from operating chips usually causes dysfunction of the integrated circuit structure. When the temperature of the chip increases, it becomes relevant for cases of relatively small-cross-section wires, because such temperature increase may affect the normal behavior of integrated circuit structure. Thus, the problem of heat dissipation in integrated circuit structures has attracted increasing interest in recent years due to the miniaturization of semiconductor devices.

### SUMMARY

To solve the problems of the above-mentioned prior art, the present invention discloses an integrated circuit structure comprising a semiconductor substrate, an active device disposed on a first region of the semiconductor substrate, a layer stack disposed on a second region of the semiconductor substrate, a through via penetrating through the layer stack and the semiconductor substrate, and a third dielectric layer between the through via and the semiconductor substrate. In one embodiment of the present invention, the layer stack includes a first dielectric layer disposed on the semiconductor substrate and a heat-conducting member disposed on the first dielectric layer.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set is forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIGS. 1 through 5 illustrate a method for forming an integrated circuit structure with a through via for heat evacuating in accordance with one embodiment of the present invention;

FIG. 6 illustrates an integrated circuit structure with a through via for heat evacuating in accordance with one embodiment of the present invention; and

FIG. 7 illustrates an integrated circuit structure with a through via for heat evacuating in accordance with one embodiment of the present invention.

### DETAILED DESCRIPTION

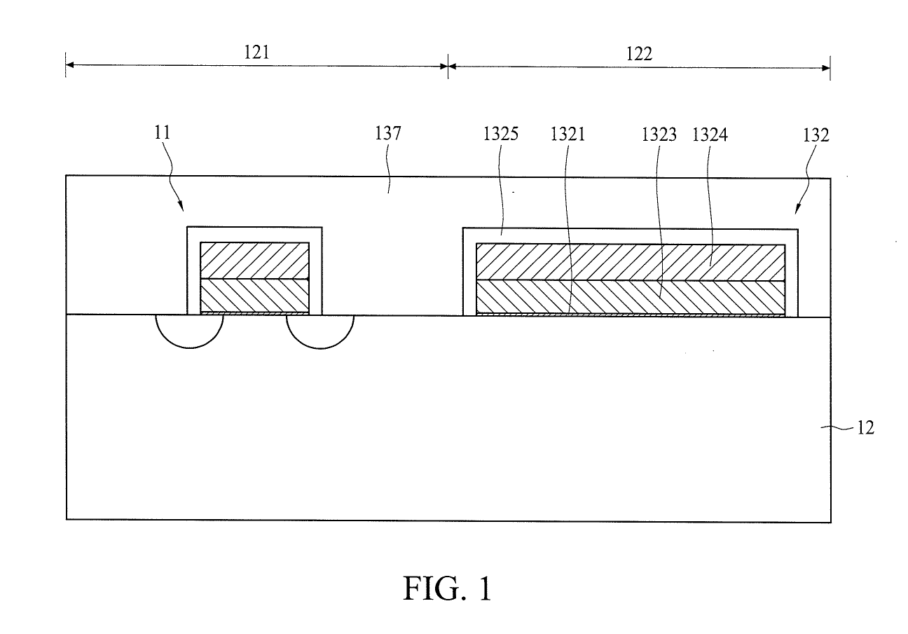

FIGS. 1 through 5 are cross-sectional views illustrating a method for forming an integrated circuit structure 10A with a through via 141 for heat evacuating in accordance with one embodiment of the present invention. Referring to FIG. 1, in one embodiment of the present invention, fabrication processes are performed to form an active device such as a transistor 11 in a first region 121 of a semiconductor substrate 12 such as a silicon substrate and a layer stack 132 in a second region 122 of a semiconductor substrate 12, and a dielectric layer 137 is then formed to cover the transistor 11 and the layer stack 132.

In one embodiment of the present invention, the layer stack 132 includes a dielectric layer such as a silicon oxide layer 1321 disposed on the semiconductor substrate 12, a polysilicon layer 1323 disposed on the oxide layer 1321, and a metal layer 1324 disposed on the polysilicon layer 1323. In one embodiment of the present invention, a dielectric layer such as a silicon nitride layer 1325 is then formed to cover the oxide layer 1321, the polysilicon layer 1323 and the metal layer 1234.

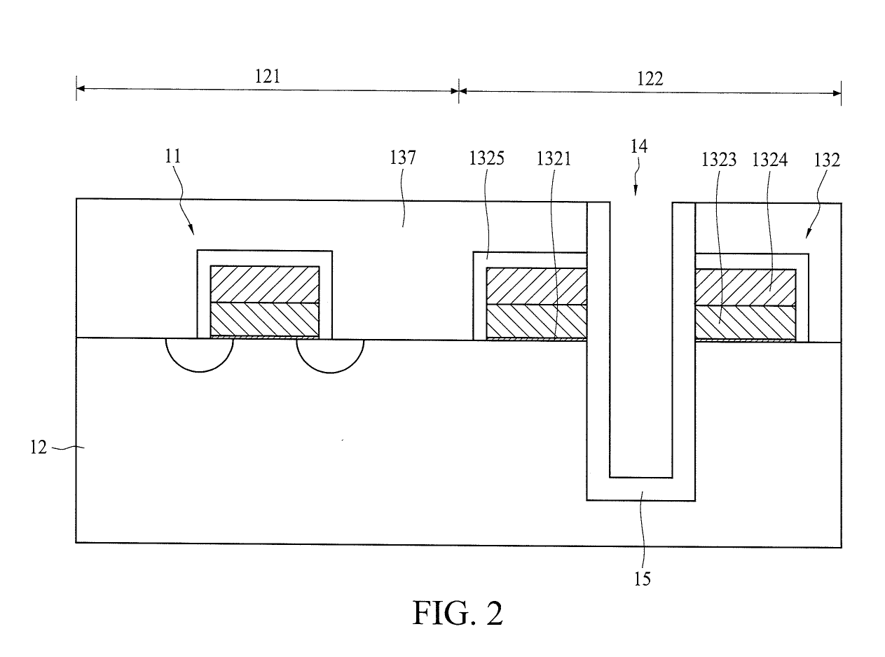

Referring to FIG. 2, in one embodiment of the present invention, photolithographic and etching processes are performed to form one or more holes 14 in the layer stack 132. In the embodiment shown in FIG. 2, the hole 14 penetrates through the layer stack 132. Subsequently, a dielectric layer 15 such as an oxide layer is the formed on the sidewall and bottom surface of the hole 14 by a conventional deposition method. In another embodiment of the present invention (not shown), the hole 14 penetrates through both the layer stack 132 and the semiconductor substrate 12.

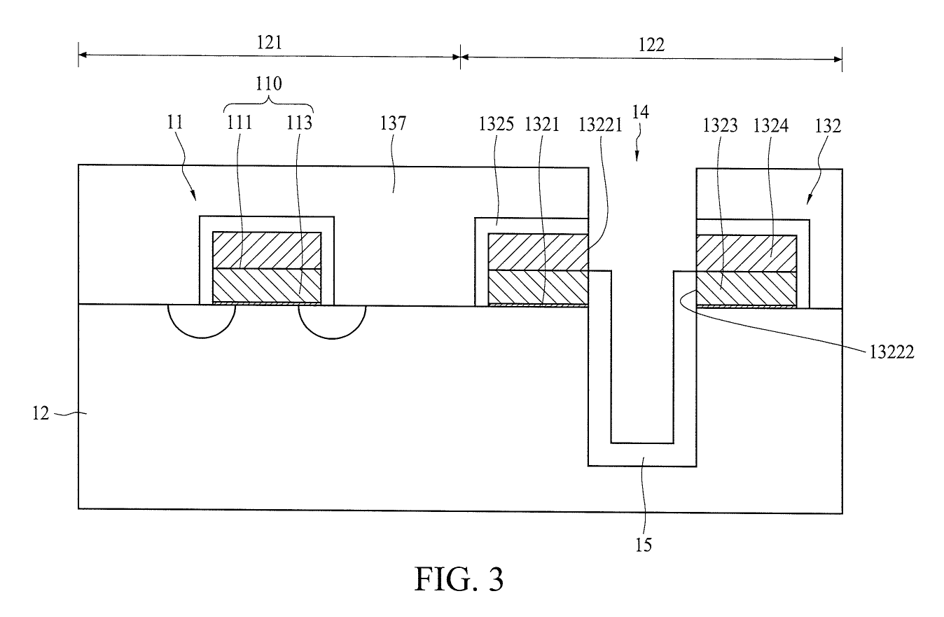

Referring to FIG. 3, in one embodiment of the present invention, the dielectric layer 15 is partially etched such that a portion of the sidewall 13221 of the layer stack 132 is exposed to the hole 14. In one embodiment of the present invention, only the sidewalls of the metal layer 1324 and the nitride layer 1325 are exposed to the hole 14 such that the dielectric layer 15 still covers the lateral surfaces 13222 of the polysilicon layer 1323 and the oxide layer 1321. In another embodiment (not shown) of the present invention, the sidewall of the polysilicon layer 1323 can also be exposed to the hole 14. To form proper electrical insulation characteristic between the material subsequently filling the hole 14 and the diffusion region of the transistor 11, the sidewall of the oxide layer 1321 should be covered by the dielectric layer 15.

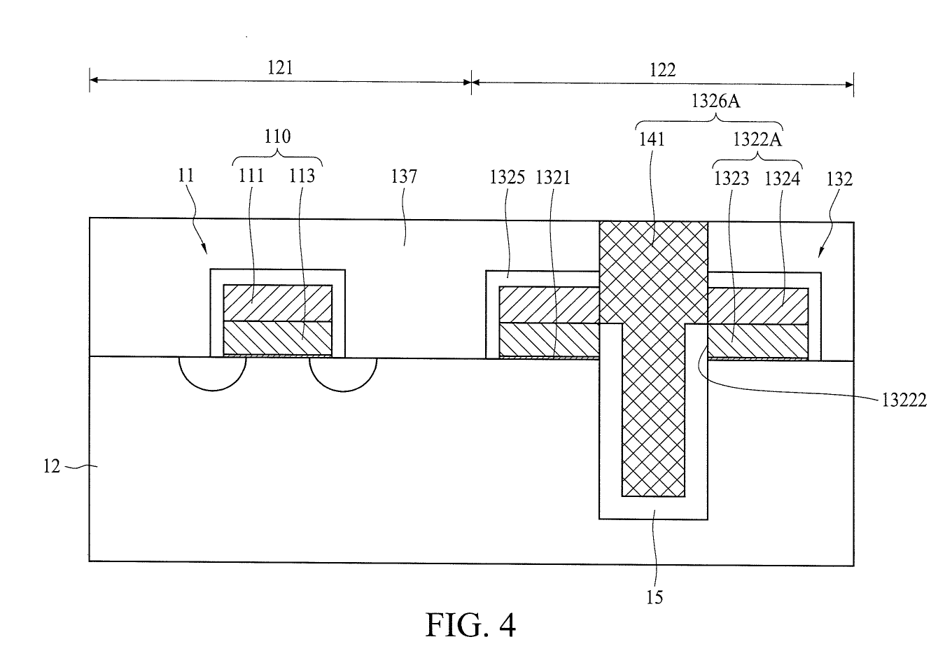

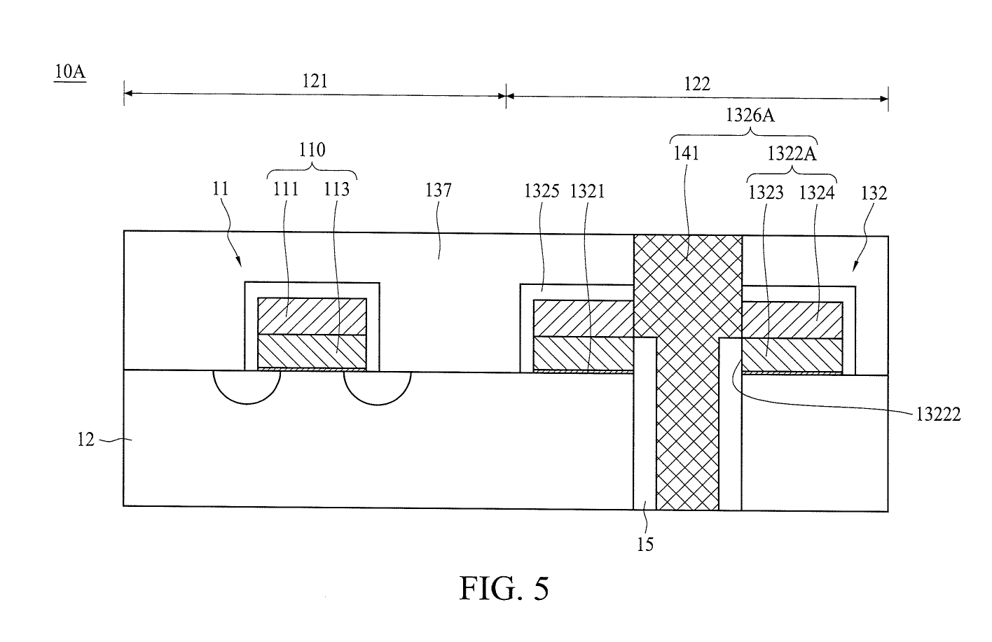

Referring to FIG. 4, heat-conducting material is then filled in the hole 14 to form a through via 141, and a polishing process is then performed to remove portion of the semiconductor substrate 12 from the bottom side so as to complete the integrated circuit structure 10A. In particular, the polishing process removes the bottom portion of the semiconductor substrate 12 so as to expose the bottom surface of the through via 141, such that the through via 141 penetrates through the layer stack 132 and the semiconductor substrate 12, as shown in FIG. 5.

In one embodiment of the present invention, the polysilicon layer 1323 and the metal layer 1324 forms a heat-conducting member 1322A, and the heat-conducting member 1322A and the through via 141 forms a heat conductor 1326A of the integrated circuit structure 10A for evacuating the operating heat generated by the transistor 11 from the semiconductor substrate 12 to the outside of the integrated circuit structure 10A. In another embodiment of the present invention, the heat-conducting material could be selected from the group consisting of tin, tungsten, copper, polysilicon and a combination thereof. In this embodiment shown in FIG. 4, the heat-conducting material is metal and connected to the metal layer 1324, which is disposed on the polysilicon layer 1323, and the dielectric layer 137 is configured to electrically isolate the heat conductor 1326A from the transistor 11.

In one embodiment of the present invention, the transistor 11 includes a gate conductor 110 above the semiconductor substrate 12, and the layer structure of the gate conductor 110 is substantially the same as that of the heat-conducting member 1322A, i.e., the gate conductor 110 includes a polysilicon layer 111 and a metal layer 113, and can be fabricated in the same process as the polysilicon layer 1323 and the metal layer 1324 of the layer stack 132. In one embodiment of the present invention, the through via 141 substantially penetrates through the center of the heat-conducting member 1322A such that the heat conductor 1326 has an antenna profile.

In one embodiment of the present invention, the distance between the transistor 11 and the dielectric layer 15 is preferably between 4 pm and 8 pm so as to prevent the through via 141 from interfering with the transistor 11. In addition, in order to ensure sufficient insulation characteristics of the dielectric layer 15, the thickness of the dielectric layer 15 is preferably between 0.5 μm and 2 μm. Due to the miniaturization of the integrated circuit structure 10A, the chip-operating heat usually causes unexpected effects on the integrated circuit structure device. Since the heat conductor 1326A including the polysilicon layer 1323, the metal layer 1324 and the through via 141 is capable of conducting the operating heat of the transistor 11 away from the transistor 11, the integrated circuit structure 10A of the present invention could have a better heat dissipation result through the heat conductor 1326A.

The thermal conductivity of the oxide layer 1321 and the nitride layer 1325 is relatively low (Kox˜1.4 W/m K). Thus, the thickness of the oxide layer 1321 in the present invention is attenuated such that the transfer of the transistor-operating heat from the transistor 11 out of the integrated circuit structure 10A is implemented through the semiconductor substrate 12, the oxide layer 1321, the heat-conducing member 1322A to the upper end and the bottom end of the through via 141, while maintaining a proper insulation characteristic of the oxide layer 1321. In one embodiment of the present invention, the thickness of the oxide layer 1321 is preferably between 10 Å and 30 Å. In particular, the second region 122 of the semiconductor substrate 12 is a keep out zone where no active device is disposed such that no extra area is needed for implementing the heat conductor 1326A, while the enhanced heat-dissipation mechanism is fulfilled.

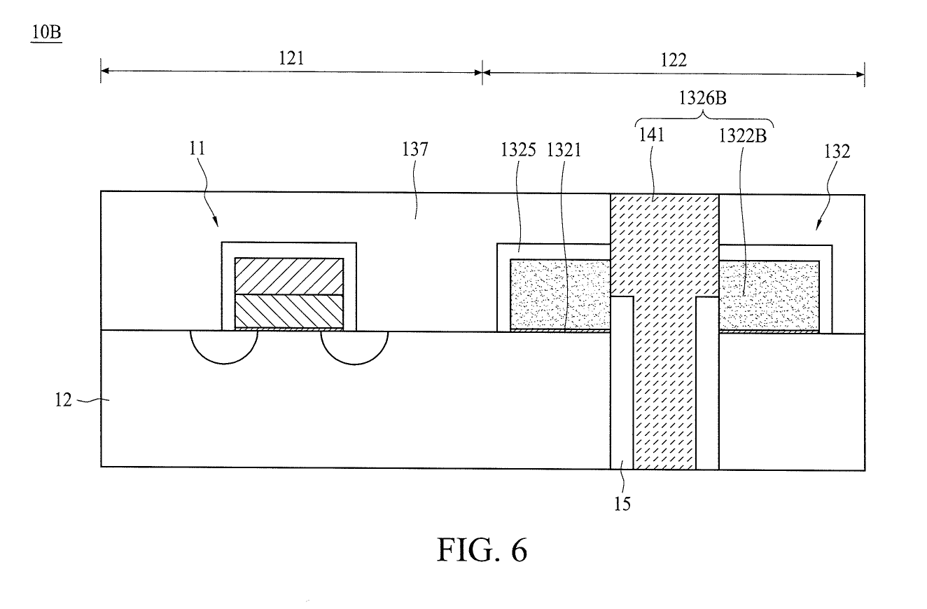

FIG. 6 illustrates an integrated circuit structure 10B according to one embodiment of the present invention. The integrated circuit structure 10B includes a heat conductor 1326B having a through via 141 and a heat-conducting member 1322B disposed on the oxide layer 1321. In the integrated circuit structure 10A shown FIG. 4, since the thermal expansion coefficient of the polysilicon layer 1323 is different from that of the metal layer 1324, stress might be generated due to the difference in thermal expansion coefficient between the polysilicon layer 1323 and the metal layer 1324. To solve this stress, the integrated circuit structure 10B shown in FIG. 5 uses a heat-conducing member 1322B of a single layer with a single thermal expansion coefficient instead of using composite layers having different thermal expansion coefficients. In one embodiment of the present invention, the heat-conducting member 1322B could be made of material selected from the group consisting of tin, tungsten, copper, polysilicon and a combination thereof.

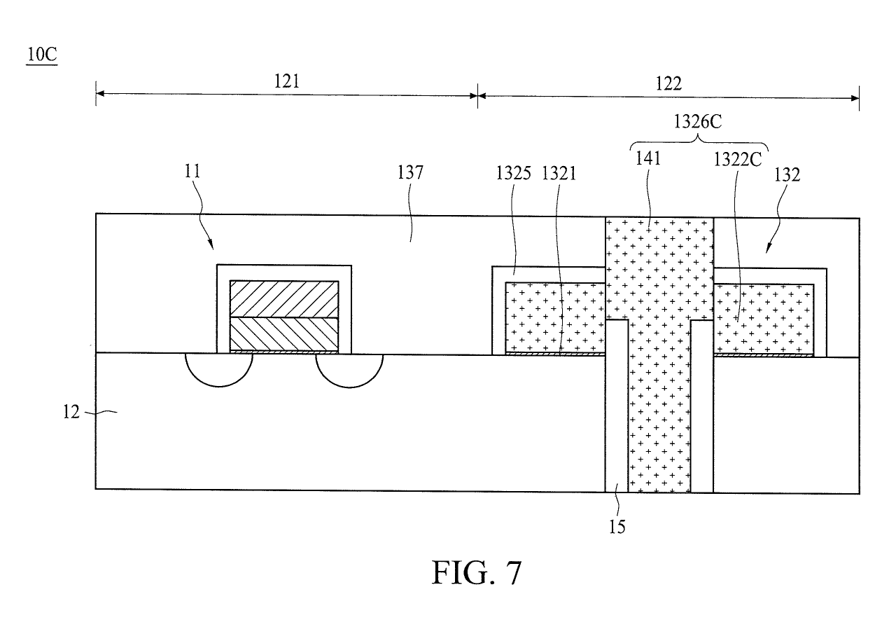

FIG. 7 illustrates an integrated circuit structure 10C according to one embodiment of the present invention. The integrated circuit structure 10C includes a heat conductor 1326C having a through via 141 and a heat-conducting member 1322C disposed on the oxide layer 1321. In the integrated circuit structure 10B shown FIG. 5, in case that the through via 141 and the heat-conducting member 1322B are made of different material having different thermal expansion coefficients, stress might be generated due to the difference in thermal expansion coefficient between the through via 141 and the heat-conducting member 1322B. To solve this stress, the through via 141 and the heat-conducting member 1322C of the integrated circuit structure 10C shown in FIG. 6 are made of the same material with a single thermal expansion coefficient. In one embodiment of the present invention, the heat-conducting member 1322C could be made of material selected from the group consisting of tin, tungsten, copper, polysilicon. Particularly, the heat conductor 1326C is composed of polysilicon so that the difference in mechanical characteristic between the heat conductor 1326C and the silicon substrate 12 can be compensated and the fracture of the package can be avoided.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure, comprising:
a semiconductor substrate;
an active device disposed on a first region of the semiconductor substrate;
a layer stack disposed on a second region of the semiconductor substrate, the layer stack including a first dielectric layer disposed on the semiconductor substrate, a heat-conducting member disposed on the first dielectric layer, and a third dielectric layer covering the heat-conducting member;
a through via penetrating through the layer stack and the semiconductor substrate; and
a third dielectric layer disposed between the through via and the semiconductor substrate.

2. The integrated circuit structure of claim 1, wherein the through via and the heat-conducting member are connected for conducting the operating heat generated by the active device through the semiconductor substrate and the first dielectric layer.

3. The integrated circuit structure of claim 1, wherein the heat-conducting member includes a polysilicon layer disposed on the first dielectric layer and a metal layer disposed on the polysilicon layer.

4. The integrated circuit structure of claim 1, wherein the heat-conducting member is made of a material selected from the group consisting of tin, tungsten, copper, polysilicon and a combination thereof.

5. The integrated circuit structure of claim 1, wherein the through via and the heat-conducting member are made of the same material.

6. The integrated circuit structure of claim 1, wherein a thickness of the first dielectric layer is between 10 Å and 30 Å.

7. The integrated circuit structure of claim 1, wherein a thickness of the third dielectric layer is between 0.5 μm and 2 μm.

8. The integrated circuit structure of claim 1, wherein the active device includes a gate conductor, and the layer structure of the gate conductor is the same as that of the heat-conducting member.

9. The integrated circuit structure of claim 1, wherein the through via substantially penetrates through the center of the heat-conducting member.

10. An integrated circuit structure, comprising:
a semiconductor substrate;
an active device disposed on a first region of the semiconductor substrate;
a first dielectric layer disposed on a second region of the semiconductor substrate;
a heat conductor including a heat-conducting member disposed on the first dielectric layer and a through via penetrating through the heat conductor and the semiconductor substrate;
a second dielectric layer disposed between the through via and the semiconductor substrate; and
a third dielectric layer isolating the heat conductor from the active device.

11. The integrated circuit structure of claim 10, wherein the heat conductor is configured to evacuate the operating heat generated by the active device through the semiconductor substrate and the first dielectric layer.

12. The integrated circuit structure of claim 10, wherein the heat-conducting member includes a polysilicon layer disposed on the first dielectric layer and a metal layer disposed on the polysilicon layer.

13. The integrated circuit structure of claim 10, wherein the heat-conducting member is made of a material selected from the group consisting of tin, tungsten, copper, polysilicon and a combination thereof.

14. The integrated circuit structure of claim 10, wherein the through via and the heat-conducting member are made of the same material.

15. The integrated circuit structure of claim 10, wherein a thickness of the first dielectric layer is between 10 Å and 30 Å.

16. The integrated circuit structure of claim 10, wherein a thickness of the second dielectric layer is between 0.5 μm and 2 μm.

17. The integrated circuit structure of claim 10, wherein the active device includes a gate conductor, and the layer structure of the gate conductor is the same as that of the heat-conducting member.

18. The integrated circuit structure of claim 10, wherein the through via substantially penetrates through the center of the heat-conducting member.
